(19) United States
(12) Patent Application Publication
(10) Pub. No.: US 2015/0244351 A1
(43) Pub. Date: Aug. 27, 2015

(54) SEMICONDUCTOR INTEGRATED CIRCUIT APPARATUS AND POWER CONSUMPTION REDUCTION METHOD THEREOF

(71) Applicant: FUJITSU LIMITED, Kawasaki-shi (JP)

(72) Inventor: Keigo TAKEDA, Shinagawa (JP)

(21) Appl. No.: 14/549,590

(22) Filed: Nov. 21, 2014

(30) Foreign Application Priority Data
Feb. 21, 2014 (JP) 2014-032081

(51) Int. Cl. H03K 3/012; H03K 3/356

(52) U.S. Cl. CPC H03K 3/012; H03K 3/356

(57) ABSTRACT

A semiconductor integrated circuit apparatus includes a plurality of circuit blocks configured to include a plurality of latch circuits connected via a data path, and a chopper to output a clock to have operations of the latch circuits synchronized; and an amplitude adjustment circuit configured to be capable of adjusting an amplitude of the clock of each of the circuit blocks to a voltage different from each other.

### CROSS-REFERENCE TO RELATED APPLICATIONS

This application is based upon and claims the benefit of priority of the prior Japanese Priority Application No. 2014-032081 filed on Feb. 21, 2014, the entire contents of which are hereby incorporated by reference.

### FIELD

The disclosures herein generally relate to a semiconductor integrated circuit apparatus and a power consumption reduction method thereof.

### BACKGROUND

Conventionally, a technology has been known that reduces power consumption of a semiconductor integrated circuit, by setting the power supply voltage of the semiconductor integrated circuit as a whole to a value as low as possible within a range where a sequential circuit having a critical path performs a normal operation in the semiconductor integrated circuit (for example, see Patent Document 1).

### RELATED-ART DOCUMENTS

### Patent Documents

[Patent Document 1] Japanese Laid-open Patent Publication No. 11-296243

When the power supply voltage of a semiconductor integrated circuit as a whole is lowered, not only the power consumption of the semiconductor integrated circuit is reduced, but also the performance of the semiconductor integrated circuit is also reduced because the propagation delay time of a data path between latch circuits in the semiconductor integrated circuit increases.

However, if the propagation delay time of the data path varies among multiple circuit blocks in the semiconductor integrated circuit due to a manufacturing variation, the power supply voltage of the semiconductor integrated circuit as a whole cannot be lowered below a highest voltage value among the lowest voltages required for the normal operation of the multiple circuit blocks. Therefore, some of the circuit blocks may still have a room for reducing the power consumption.

### SUMMARY

According to at least an embodiment of the present invention, a semiconductor integrated circuit apparatus includes a plurality of circuit blocks configured to include a plurality of latch circuits connected via a data path, and a chopper to output a clock to have operations of the latch circuits synchronized; and an amplitude adjustment circuit configured to be capable of adjusting an amplitude of the clock of each of the circuit blocks to a voltage different from each other.

The object and advantages of the embodiment will be realized and attained by means of the elements and combinations particularly pointed out in the claims. It is to be understood that both the foregoing general description and the following detailed description are exemplary and explanatory and are not restrictive of the invention as claimed.

### BRIEF DESCRIPTION OF DRAWINGS

FIG. 1 is a configuration diagram illustrating an example of a semiconductor integrated circuit apparatus;

FIG. 2 is a configuration diagram illustrating an example of a sequential circuit;

FIG. 3 is a diagram illustrating an example of a variation of a manufacturing process among semiconductor integrated circuit apparatuses;

FIG. 4 is a diagram illustrating an example of a variation of a manufacturing process within a semiconductor integrated circuit apparatus;

FIG. 5 is a configuration diagram illustrating an example of a chopper;

FIG. 6 is a timing chart illustrating an example of input/output waveforms of a chopper;

FIG. 7 is a configuration diagram illustrating an example of an amplitude adjustment circuit;

FIG. 8 is a configuration diagram illustrating an example of a malfunction detection circuit;

FIG. 9 is a timing chart illustrating an example of an operation of a malfunction detection circuit;

FIG. 10 is a timing chart illustrating an example of an operation of a malfunction detection circuit;

FIG. 11 is a timing chart illustrating an example of an operation of a malfunction detection circuit;

FIG. 12 is a timing chart illustrating an example of an operation of a malfunction detection circuit;

FIG. 13 is a flowchart illustrating an example of an operation of a state machine;

FIG. 14 is a flowchart illustrating an example of an operation of an amplitude adjustment circuit;

FIG. 15 is a configuration diagram illustrating an example of a malfunction detection circuit;

FIG. 16 is a configuration diagram illustrating an example of a malfunction detection circuit;

FIG. 17 is a configuration diagram illustrating an example of a malfunction detection circuit;

FIG. 18 is a configuration diagram illustrating an example of a malfunction detection circuit;

FIG. 19 is a configuration diagram illustrating an example of a circuit to simulate a power consumption reduction effect;

FIG. 20 is a diagram illustrating an example of a simulation result;

FIG. 21 is a diagram illustrating an example of a simulation result;

FIG. 22 is a diagram illustrating an example of a case where there is no manufacturing variation in a semiconductor integrated circuit apparatus;

FIG. 23 is a diagram illustrating an example of a case where there is a manufacturing variation in a semiconductor integrated circuit apparatus;

FIG. 24 is a diagram illustrating an example of a simulation result;

FIG. 25 is a diagram illustrating an example of a simulation result;

FIG. 26 is a diagram illustrating an example of a simulation result; and

FIG. 27 is a diagram illustrating an example of a simulation result.

### DESCRIPTION OF EMBODIMENTS

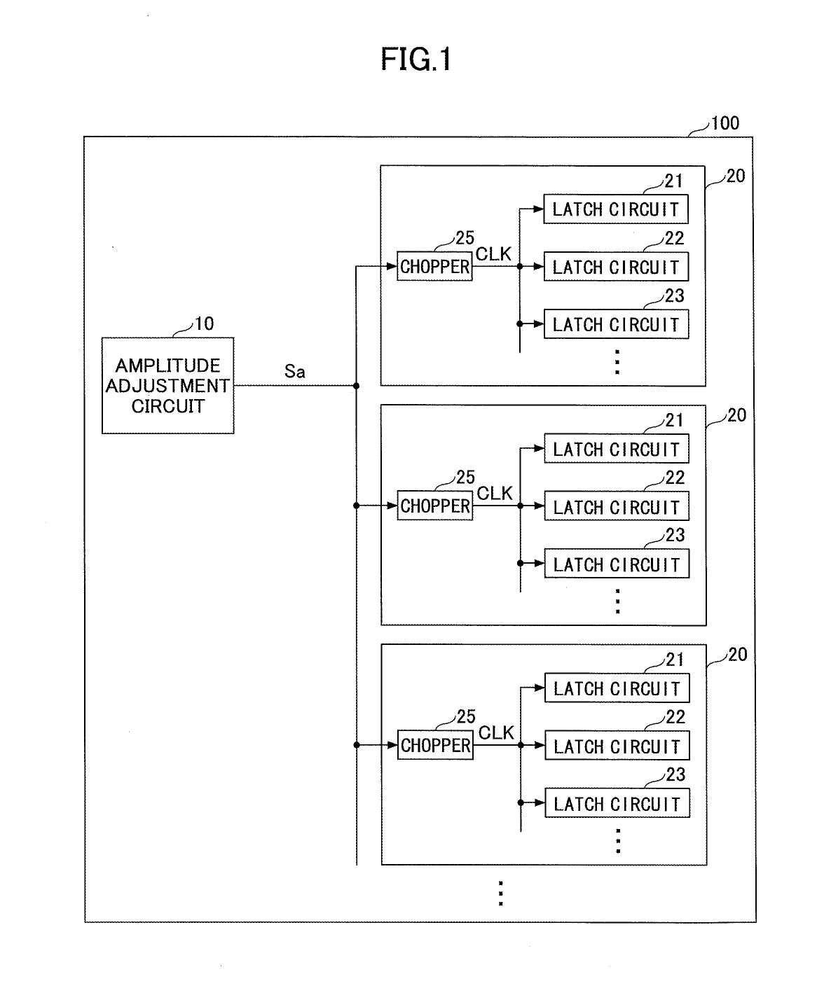

FIG. 1 is a configuration diagram illustrating an example of a semiconductor integrated circuit apparatus 100 (simply referred to as an “apparatus 100” below). The apparatus 100 is an example of an LSI (Large Scale Integrated circuit), which includes multiple sequential circuits 20 and an amplitude adjustment circuit 10.

The multiple sequential circuits 20 have the same circuit configuration, and each of the multiple sequential circuits 20 includes multiple latch circuits 21, 22, and 23, and a chopper 25 that outputs a clock CLK with a full-swing amplitude, to synchronize operations of the multiple latch circuits 21, 22, and 23. The multiple latch circuits 21, 22, and 23 are driven by the common clock CLK output from the chopper 25 in each of the sequential circuits 20. The chopper 25 has a function to vary the amplitude of the clock CLK depending on an amplitude adjustment signal Sa supplied from the amplitude adjustment circuit 10.

The amplitude adjustment circuit 10 is an example of a unit to output the amplitude adjustment signal Sa to the choppers 25 for adjusting the amplitude of the clock CLK output from the chopper 25 in each of the sequential circuits 20. The amplitude adjustment circuit 10 automatically adjusts the amplitude of the clock CLK to a voltage with which the apparatus 100 does not underperform a predetermined target performance, to reduce the power consumption of the apparatus 100.

For example, the power consumption of a CMOS circuit forming the sequential circuit 20 under operation changes according to “CxV²xf” where C is the load capacitance, f is the switching frequency, and V is the power supply voltage. Therefore, by making the amplitude of the clock CLK smaller, which may otherwise vibrate with a full-swing amplitude of the power supply voltage V, the power supply voltage V is lowered, and hence, the power consumption of the chopper 25 under operation can be lowered. The power consumption of the choppers 25 can be lowered, and hence, the power consumption of the apparatus 100 can be lowered as a whole.

The amplitude adjustment circuit 10 may be a circuit that adjusts the amplitudes of the clocks CLK to be output from the respective choppers 25 in the respective sequential circuits 20 to the same voltage, or may be a circuit that adjusts the amplitudes to voltages different from each other. By being capable of adjusting the amplitudes of the clocks CLK to voltages different from each other, the power consumption can be reduced by units of the respective sequential circuits 20. One amplitude adjustment circuit 10 may be provided for multiple choppers 25, or may be provided for one chopper 25.

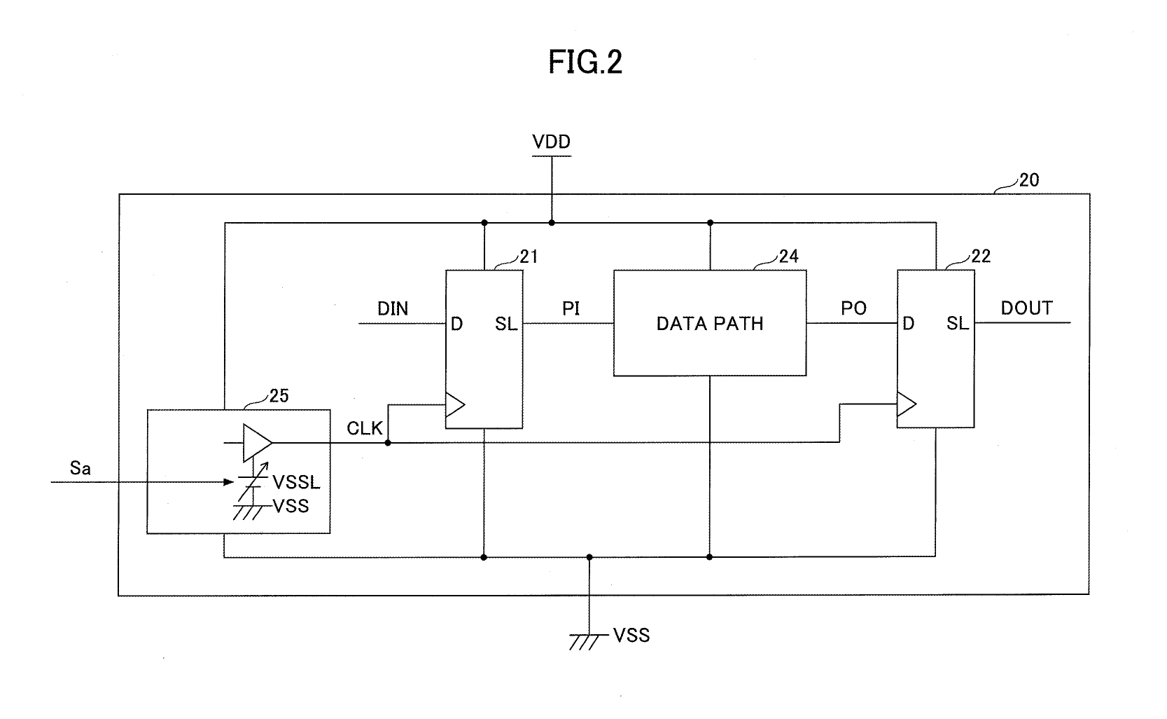

FIG. 2 is a diagram illustrating an example of the sequential circuit 20. The sequential circuit 20 includes multiple latch circuits 21 and 22 connected with each other via a data path 24, and a chopper 25. The chopper 25 is a circuit that outputs the clock CLK to synchronize operations between the multiple latch circuits 21 and 22 to transmit or receive a signal via the data path 24.

Note that although FIG. 2 illustrates a case where the number of latch circuits driven by the common clock CLK is two, the number of latch circuits may be three or more. Also, the latch circuits 21 and 22 are, for example, D flip-flops.

A data output terminal SL of the latch circuit 21 is connected with a data input terminal D of the latch circuit 22 via the data path 24. The clock CLK is a signal that is supplied to clock input terminals of the latch circuits 21 and 22, respectively. The data path 24 is a combinational logic circuit or a comparatively long wire. A signal PI output from the data output terminal SL of the latch circuit 21 propagates through the data path 24, to be converted into a signal PO corresponding to the signal PI. The converted signal PO is input into the data input terminal D of the latch circuit 22.

The latch circuit 21 holds input data DIN input from the data input terminal D synchronized with the clock CLK to output the signal PI, whereas the latch circuit 22 holds the signal PO synchronized with the clock CLK to output the output data DOUT from the data output terminal SL.

The propagation delay time of a CMOS circuit forming the sequential circuit 20 changes according to “C/V” where C represents the load capacitance and V represents the power supply voltage. Namely, when the load capacitance C is smaller, or the power supply voltage V is higher, the propagation delay time of the CMOS circuit is shorter. Therefore, if the power supply voltage V is lowered, the propagation delay time of the CMOS circuit becomes longer, and the performance of the apparatus 100 is reduced. For example, if the power supply voltage V is lowered, the operation frequency of the apparatus 100 is reduced.

The amplitude adjustment signal Sa supplied from the amplitude adjustment circuit 10 is not a control signal to reduce the power supply voltage V (a potential difference between a terminal VDD and a terminal VSS) of the sequential circuit 20 as a whole, but a control signal to adjust a reduction amount of the amplitude of the clock CLK. Therefore, circuits whose the propagation delay time of the CMOS circuit become longer are the latch circuits 21 and 22, which are driven by the clock CLK output from the chopper 10, not the data path 24. Namely, if the amplitude of the clock CLK is made smaller, the propagation delay time of the data path 24 does not increase and remains unchanged although the propagation delay time increases for data that is input and output from each of the latch circuits (namely, the propagation delay time of the latch circuit 21 or 22 increases).

However, instead of making the amplitude of the clock CLK smaller, if the power supply voltage V of the sequential circuit 20 as a whole is lowered, not only the propagation delay time of the latch circuit 21 or 22 increases, but also the propagation delay time of the data path 24 also increases. This is because the data path 24 operates depending on the power supply voltage V.

Therefore, if the actual propagation delay time of the data path 24 is shorter than a predetermined target delay time (if there is an allowance of time), the amplitude adjustment circuit 10 may make the amplitude of the clock CLK smaller by the amplitude adjustment signal Sa within a range where operations of the latches 21 and 22 can be synchronized. This does not make the propagation delay time of the data path 24 increase, which prevents the performance of the sequential circuit 20 and the apparatus 100 from reducing, and the power consumption can be reduced for the sequential circuit and the apparatus 100 as a whole because the amplitude of the clock CLK is reduced.

Also, in the present embodiment, since one or more amplitude adjustment circuits 10 to adjust the amplitude of the clock CLK output from the choppers 25 are provided in the apparatus 100, the amplitude of the clock CLK can be adjusted by units of the apparatuses 100.

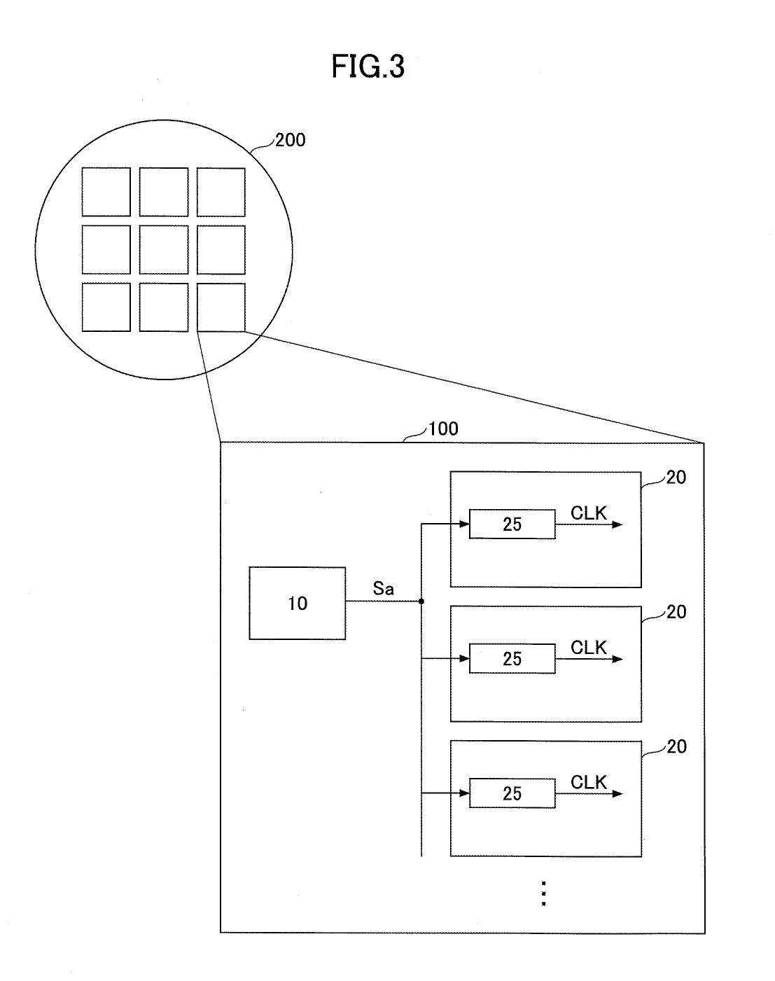

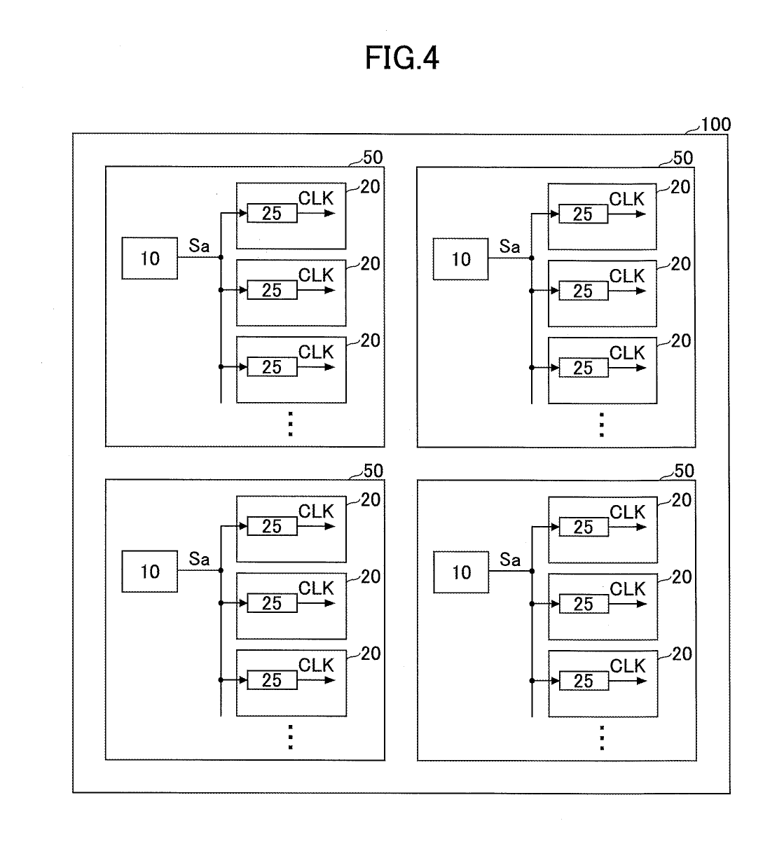

FIG. 3 is a diagram illustrating an example of a variation of a manufacturing process among semiconductor integrated circuit apparatuses 100. FIG. 4 is a diagram illustrating another example of a variation of a manufacturing process within a semiconductor integrated circuit apparatus 100.

A variation of a manufacturing process (manufacturing variation) is a phenomenon where even if transistors have the same layout and the same size by design, individual manufactured transistors have different values of characteristics such as the threshold voltage or the drain current. Consequently, phenomena may be brought about such that an operational margin of the circuit is remarkably reduced, manufacturing yield is steeply reduced, and so on. Due to such a variation of transistors, a problem arises in that an operational margin of the semiconductor integrated circuit apparatus needs to be set great.

In case of FIG. 3, the apparatus 100 is one of the chips cut off from a wafer 200. Multiple apparatuses 100 are formed on the wafer 200, having circuit configurations equivalent to each other. One or more amplitude adjustment circuits 10 and choppers 25 are placed in each of the apparatuses 100. Therefore, the amplitude adjustment circuit 10 placed in each of the apparatuses 100 can reduce the power consumption of the apparatus 100 in which itself is placed, by making the amplitude of the clock CLK output from the choppers 25 smaller. Therefore, even if a manufacturing variation is generated among the apparatuses 100, the power consumption can be reduced by respective units of the apparatuses 100.

Also, each of the amplitude adjustment circuits 10 may set the amplitude of the clock CLK output from the choppers 25, for example, to a voltage derived using a critical path in the apparatus 100 in which itself is placed. This makes it possible to adjust the amplitude of the clock CLK to an optimal voltage for an individual apparatus 100 even if a manufacturing variation is generated among the apparatuses 100. Consequently, the power consumption can be reduced while suppressing the performance reduction of the apparatus 100 by units of the apparatuses 100.

On the other hand, in case of FIG. 4, an apparatus 100 includes multiple circuit blocks 50 that have circuit configurations equivalent to each other. One or more amplitude adjustment circuits 10 and choppers 25 are placed in each of the circuit blocks 50. For example, if the apparatus 100 is a multi-core processor, each of the circuit blocks 50 corresponds to a core in the multi-core processor. Therefore, the amplitude adjustment circuit 10 in each of the apparatuses 100 can reduce the power consumption of the circuit block 50 in which itself is placed, by making the amplitude of the clock CLK output from the choppers 25 smaller. Therefore, even if a manufacturing variation is generated within the apparatus 100 (in this case, in other words, a manufacturing variation among the circuit blocks 50), the power consumption can be reduced by units of the circuit blocks 50.

Also, the propagation delay time of a critical path in each of the circuit blocks 50 may be different due to the manufacturing variation within the apparatus 100. In such a case, it is preferable to have the clock CLK of the choppers 25 set by units of the circuit blocks 50.

Therefore, each of the amplitude adjustment circuits 10 may set the amplitudes of the clock CLK output from the choppers 25, for example, to a voltage derived using a critical path in the circuit block 50 in which itself is placed. This makes it possible to adjust the amplitude of the clock CLK to an optimal voltage for an individual circuit block 50 even if a manufacturing variation is generated among the circuit blocks 50. Consequently, the power consumption can be reduced while suppressing the performance reduction of the circuit block 50 by units of the circuit blocks 50.

Note that a critical path is a data path between latch circuits whose propagation delay time is equivalent to, or a bit shorter than a predetermined target delay time.

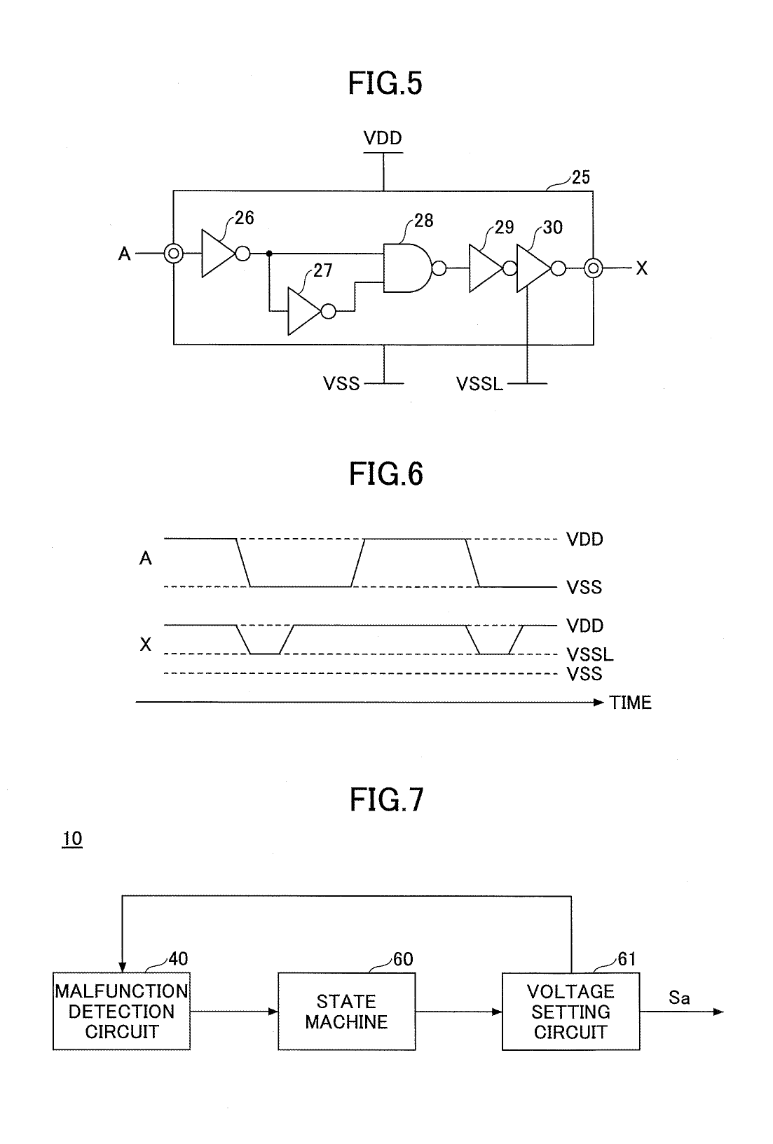

FIG. 5 is a configuration diagram illustrating an example of the chopper 25. The chopper 25 is a circuit that includes, for example, inverters 26, 27, and 29, a NAND gate 28, and a driver 30. The chopper 25 also includes, for example, a power terminal VDD, a power terminal VSS, a clock terminal A, an output terminal X, and an adjustment terminal VSSL.

The power terminal VDD is an example of a terminal that is connected with a high-potential power source, and the power terminal VSS is an example of a terminal that is connected with a low-potential power source. The potential difference between the power terminal VSS and the power terminal VDD is the power supply voltage.

The clock terminal A is an example of a terminal into which a clock signal is input. The output terminal X is an example of a terminal from which the clock CLK is output, which is the output signal of the chopper 25. The adjustment terminal VSSL is an example of a terminal into which the amplitude adjustment signal Sa is input for adjusting the amplitude of the clock CLK.

FIG. 6 is a timing chart illustrating an example of input/output waveforms of the chopper 25. The vertical axis represents voltage, and the horizontal axis represents time. FIG. 6 will be described with reference to FIG. 5. When a clock signal is input into the clock terminal A, the clock CLK is output from the output terminal X that has the low-level time width equivalent to the propagation delay time of the inverter 27. The frequency of the clock CLK is virtually the same as the frequency of the clock signal input into the clock terminal A. When the amplitude adjustment signal Sa having a positive voltage relative to the power terminal VSS is input into the adjustment terminal VSSL, the clock CLK is output from the driver 30 via the output terminal X, which has the amplitude narrower than the clock signal input into the clock terminal A, by the voltage input into the adjustment terminal VSSL. The amplitude of the clock CLK is adjusted by having the ground potential of the driver 30 adjusted by the amplitude adjustment signal Sa.

By having the clock CLK input into the clock signal input terminal of each latch circuit, the latch circuit is driven. When the amplitude of the clock CLK is made smaller, the propagation delay time of the driven latch circuit becomes longer. If the propagation delay time of the latch circuit is equivalent to or a bit shorter than a target delay time, and the amplitude of the clock CLK is made smaller, then, a delay of the data output of the latch circuit becomes greater, and the propagation delay time may exceed the target delay time (over delay). Therefore, the amplitude adjustment circuit 10 adjusts the amplitude of the clock CLK so that the propagation delay time of the latch circuit does not exceed the target delay time.

FIG. 7 is a configuration diagram illustrating an example of an amplitude adjustment circuit. The amplitude adjustment circuit 10 includes a malfunction detection circuit 40, a state machine 60, and a voltage setting circuit 61. The malfunction detection circuit 40 is a circuit to detect a synchronization failure between the latch circuits when the output amplitude of the chopper is reduced, by using the critical path of the apparatus 100 or the circuit block 50. The state machine 60 is a circuit to search for an optimum value of VSSL voltage (voltage of the amplitude adjustment signal Sa) input into the adjustment terminal VSSL of the chopper 25 (see FIG. 5). The voltage setting circuit 61 is a circuit to set the optimum value of VSSL voltage searched by the state machine 60 to the adjustment terminal VSSL of the chopper 25.

The output of the malfunction detection circuit 40 is input into the state machine 60, and the output of the state machine 60 is input into the voltage setting circuit 61. The output voltage value of the voltage setting circuit 61 is fed back to the malfunction detection circuit 40, and the output voltage value is changed until an optimal VSSL voltage is obtained. When the setting of VSSL voltage is completed, the optimum value of VSSL voltage is distributed to the choppers 25 that drive the latch circuits in the apparatus 100. In this way, by providing the amplitude adjustment circuit 10 for each of the apparatuses 100 or the circuit blocks 50, it is possible to deal with a manufacturing variation.

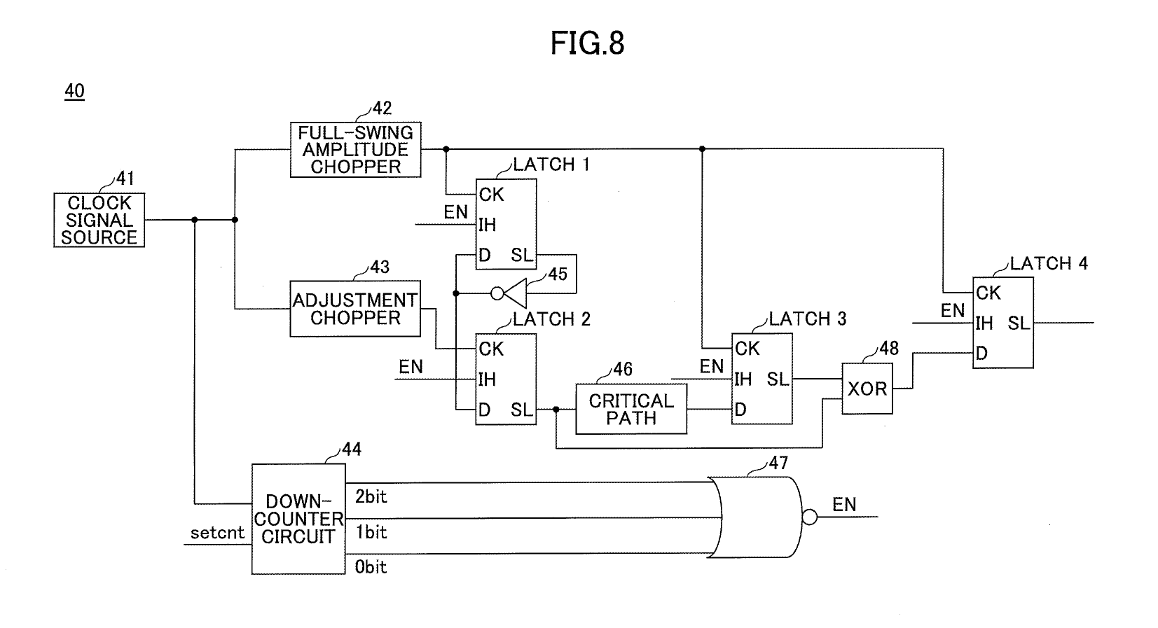

FIG. 8 is a configuration diagram illustrating an example of the malfunction detection circuit 40 that includes an adjustment chopper 43 having the same circuit configuration as the chopper 25. The malfunction detection circuit 40 is a circuit to detect a lower limit value of the amplitude of the clock CLK with which operations among multiple latch circuits (for example, between the latch circuits 21 and 22 in FIG. 2) can be normally synchronized, by using a critical path 46 in the apparatus 100 or the circuit block 50. The critical path 46 is a replica path having substantially the same circuit configuration as the data path used for implementing the function of the apparatus 100 or the circuit block 50. However, some circuit changes may be required to make it also operate as a buffer through which the input signal is output as it is.

The clock signal source 41 supplies a common clock signal to a full-swing amplitude chopper 42, the adjustment chopper 43, and a down-counter circuit 44. The down-counter circuit 44 is a counter having two bits or more, which can count down an arbitrary number by receiving a “setcnt” signal as input to set the count-down number. When the clock signal is input and the output of the down-counter circuit 44 is 0, a high-active EN signal (enable signal) is output from a NOR gate 47. The EN signal is connected with IH terminals of the respective latch circuits 1, 2, 3, and 4, and the outputs of the latch circuits 1, 2, 3, and 4 are fixed at immediately preceding logic levels, respectively, when the EN signal at the high level is input into the IH terminals. Based on the output level of the latch circuit 4 when the EN signal is at the high level, the state machine 60 (see FIG. 7) determines whether synchronization operations are normal between the latch circuit 2 and the latch circuit 3.

A cyclic pulse signal that is generated by the latch circuit 1 and the inverter 45 is supplied to the latch circuit 2 as data. The critical path 46 configured with buffers is connected between the latch circuit 2 and the latch circuit 3. By changing the number of levels of the buffers, the propagation delay time of the critical path 46 can be set equivalent to the target delay time, or can be set to a propagation delay time longer than the target delay time.

The latch circuit 1, the latch circuit 3, and the latch circuit 4 are driven by the clock signal having the full-swing amplitude, which is output from the full-swing amplitude chopper 42. The latch circuit 2 is driven by the clock signal having the full-swing amplitude or smaller, which is output from the adjustment chopper 43. An exclusive logical OR (XOR output) of the data output of the latch circuit 2 and the data output of the latch circuit 3 is output from an XOR gate 48, and input into the latch circuit 4. When the state machine 60 changes the output amplitude of the adjustment chopper 43, the propagation delay time of the data output of the latch circuit 2 changes.

The XOR gate 48 can detect an over delay by detecting a difference between the data signals of the latch circuit 2 and the latch circuit 3. Under a normal operation where the propagation delay time of the critical path 46 does not exceed the target delay time, the data outputs of the latch circuit 2 and the latch circuit 3 are necessarily different (inverted), and the output of the latch circuit 4 takes the high level. On the other hand, under an abnormal operation where the propagation delay time of the critical path 46 exceeds the target delay time, there is a timing during which the data outputs of the latch circuit 2 and the latch circuit 3 are equivalent to each other, and the output of the latch circuit 4 takes the low level.

Therefore, the malfunction detection circuit 40 can detect a synchronization operation failure between the latch circuit 2 and the latch circuit 3 based on a change of the logic level of the output of the latch circuit 4 during a process where the output amplitude of the adjustment chopper 43 is lowered stepwise by the state machine 60.

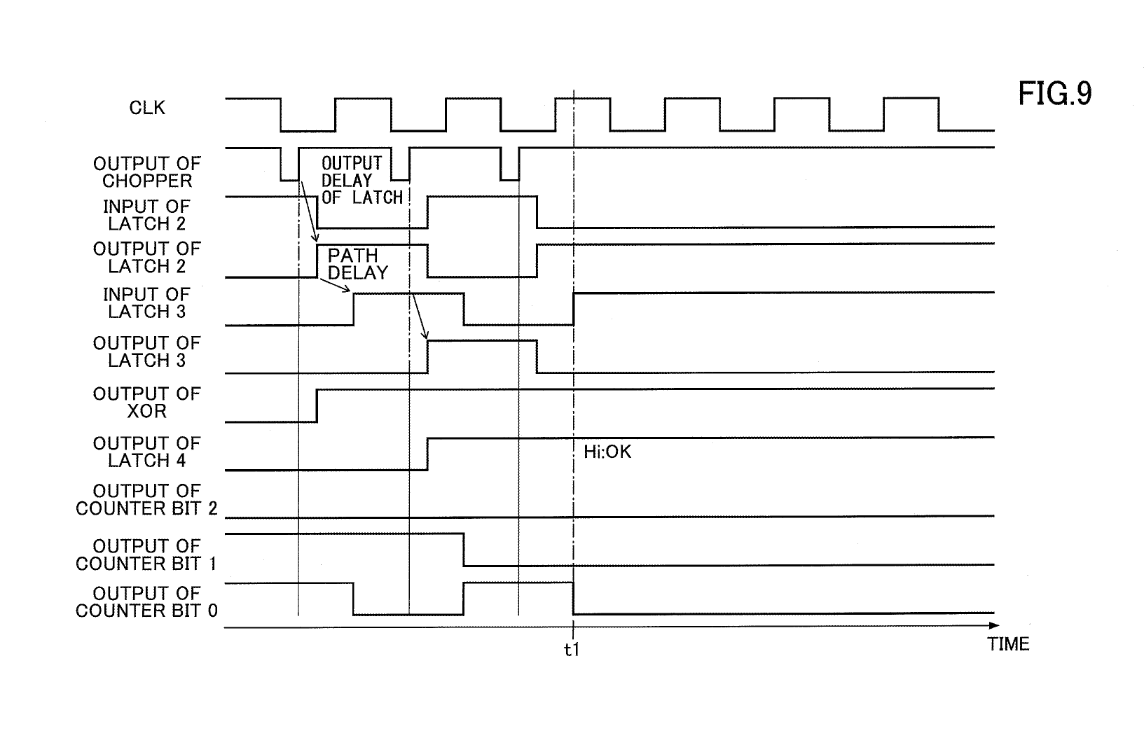

FIGS. 9 to 12 are timing charts illustrating examples of operations of the malfunction detection circuit 40 when the output amplitude is adjusted for a chopper. In FIGS. 9 to 12, a “CLK” is the clock signal of the clock signal source 41, a “chopper output” is the clock signal of the full-swing amplitude chopper 42, the vertical axis represents voltage, and the horizontal axis represents time.

Under a normal operation where the propagation delay time of the critical path 46 satisfies the target delay time (FIG. 9), the output of the latch circuit 4 takes the high-level at timing t1 when the EN signal changes from the low-level to the high-level. Based on the high-level output of the latch circuit 4, the state machine 60 can determine that synchronization operations between the latch circuit 2 and the latch circuit 3 are normal.

However, when the latch circuits are being reset, the data outputs of the latch circuit 2 and the latch circuit 3 are equivalent, the output of the latch circuit 4 takes the low-level, and the determination result of the state machine 60 indicates a false synchronization failure. To avoid determining such a false synchronization failure, the count value of the down-counter circuit 44 is set to three so that the data output of the latch circuit 4 during the reset is neglected.

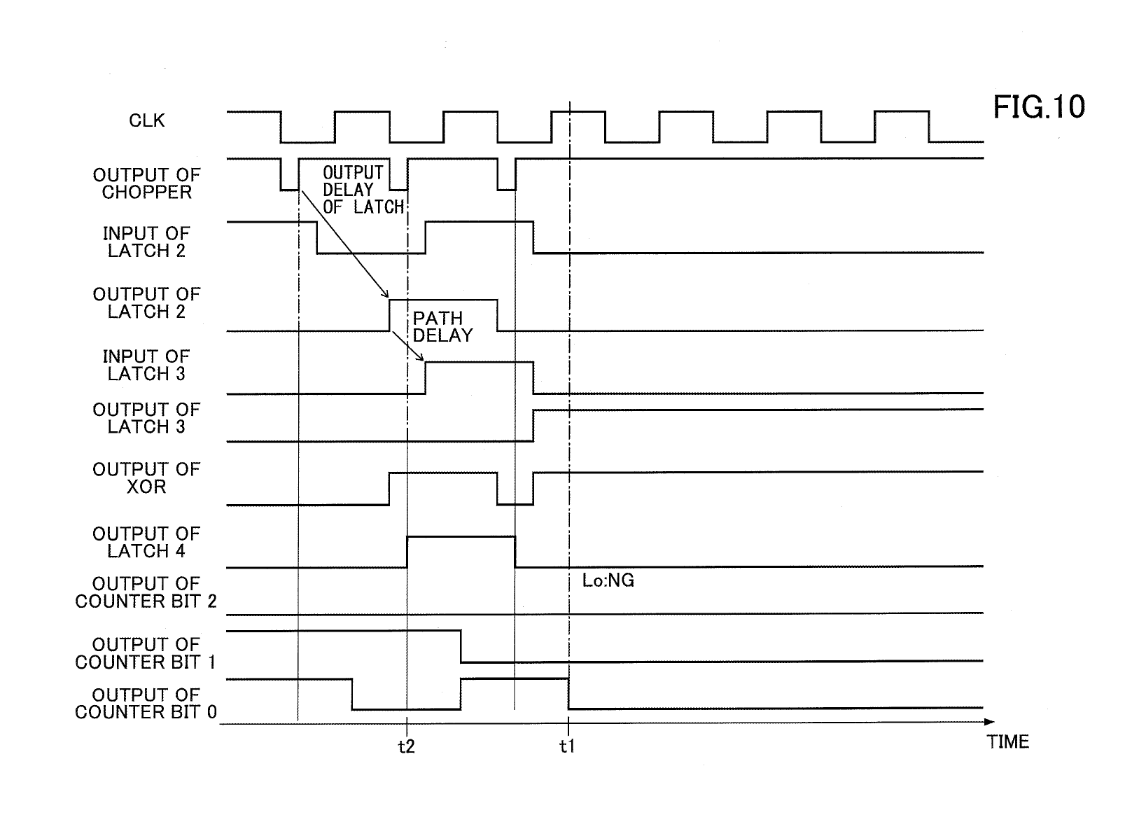

By making the output amplitude of the adjustment chopper 43 smaller so that the propagation delay time of the latch circuit 2 becomes greater to an extent where it is too late for a data capturing timing t2 of the latch circuit 3, an over delay occurs (see FIG. 10). When an over delay occurs, there is a timing during which the data outputs of the latch circuit 2 and the latch circuit 3 are equivalent to each other. Therefore, the state machine 60 can determine that synchronization operations fail between the latch circuit 2 and the latch circuit 3 based on the low-level output of the latch circuit 4.

However, due to the over delay, the output of the latch circuit 4 takes the high-level at timing t2 corresponding to the second clock, the count value of the down-counter circuit 44 is set to three so that the data output of the latch circuit 4 is neglected when the over delay occurs.

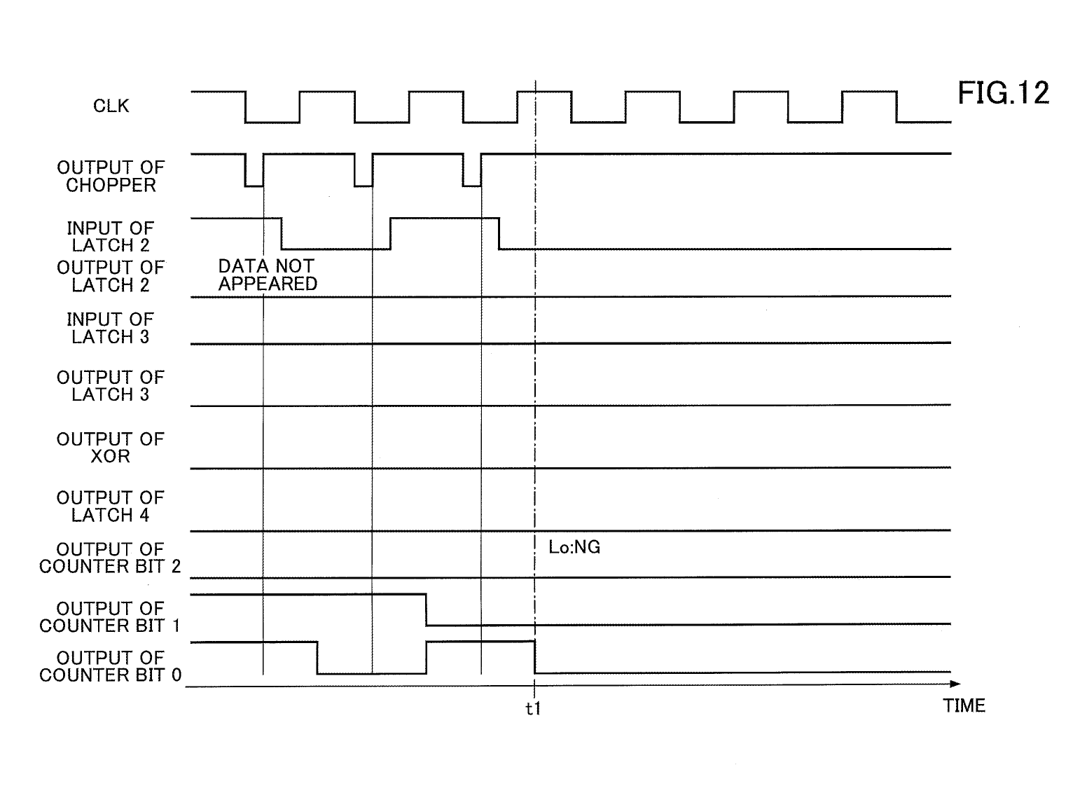

When the output amplitude of the adjustment chopper 43 becomes smaller than the detection sensitivity of the latch, the outputs of the latches are fixed to the low-level or the high-level (see FIG. 12). In this case, there is a timing during which the data outputs of the latch circuit 2 and the latch circuit 3 are equivalent to each other. Therefore, the state machine 60 can determine that synchronization operations fail between the latch circuit 2 and the latch circuit 3 based on the low-level output of the latch circuit 4.

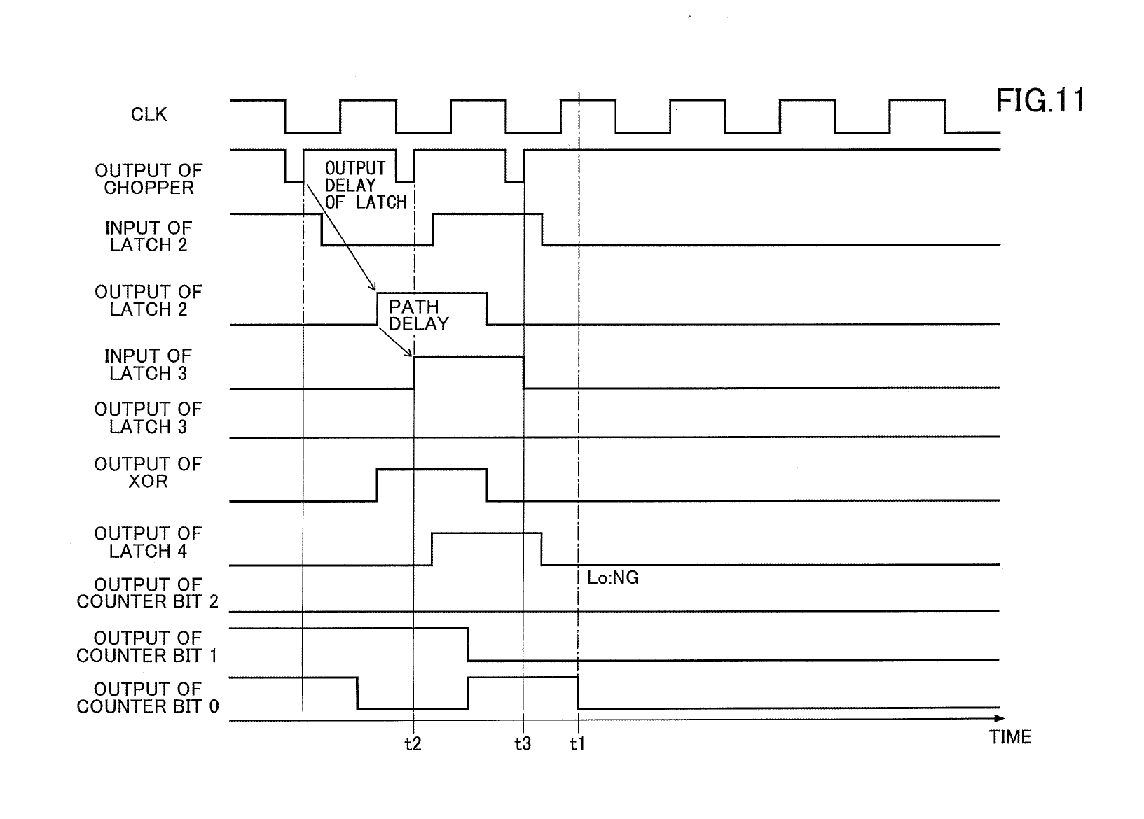

Note that the over delay in FIG. 10 is an example where the data signal is too late to be received by the latch circuit 3 at the second clock (timing t2), and the latch circuit 3 receives the data at the next third clock. The over delay in FIG. 11 is an example where the data cannot be received even at the third clock (timing t3), and the latch circuit 3 cannot receive the data before the clock signal is suppressed.

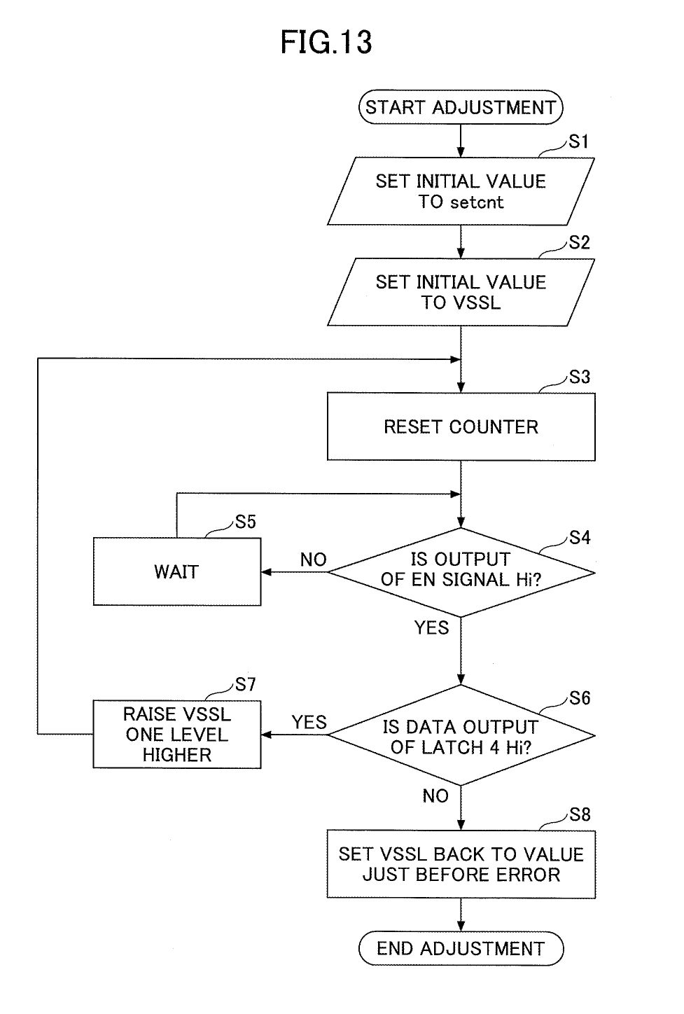

FIG. 13 is a flowchart illustrating an example of an operation of the state machine 60 when the output amplitude is adjusted for a chopper.

At Step S1, the state machine 60 sets a predetermined initial value of the “setcnt” signal to be input into the down-counter circuit 44.

At Step S2, the state machine 60 sets the initial value of the VSSL voltage to be input into the VSSL terminal of the adjustment chopper 43.

At Step S3, the state machine 60 resets the counter of the down-counter circuit 44.

At Step S4, the state machine 60 determines whether the EN signal is at the high-level, and if it is not at the high-level, waits at Step S5 until the EN signal takes the high-level.

At Step S6, the state machine 60 determines whether the data output of the latch circuit 4 is at the high-level when the EN signal is at the high-level, and at Step S7, raises stepwise the VSSL voltage that is input into the adjustment chopper 43 until the data output of the latch circuit 4 takes the low-level. If an error is detected at the latch circuit 4 (the data output of the latch circuit 4 is at the low-level), the state machine 60 executes Step S8.

At Step S8, the state machine 60 sets the immediately preceding normal value of the VSSL voltage (a normal value just before the error is detected at the latch circuit 4) as the setting value of the VSSL voltage (the optimum value of the VSSL voltage).

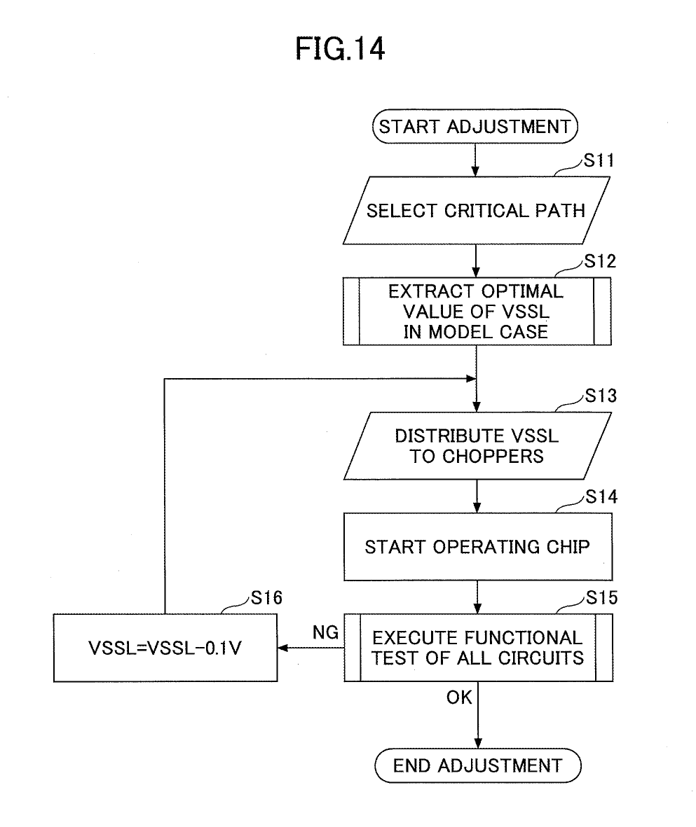

FIG. 14 is a flowchart illustrating an example of an operation of the amplitude adjustment circuit 10 when the apparatus 100 is tested. The propagation delay time of the critical path 46 is designed beforehand to be equivalent to the required target delay time by adjusting the number of levels of the buffers.

At Step S11, the amplitude adjustment circuit 10 selects a critical path used by the malfunction detection circuit 40 for failure detection, among multiple critical paths 46 implemented in the apparatus 100 beforehand.

At Step S12, the amplitude adjustment circuit 10 makes the state machine 60 operate to extract the optimum value of the VSSL voltage.

At Step S13, the amplitude adjustment circuit 10 distributes the extracted optimum value of the VSSL voltage to the choppers 25 by the voltage setting circuit 61. The choppers 25 output the clock CLK at the amplitude corresponding to the distributed optimum value of the VSSL voltage.

At Step S14, the amplitude adjustment circuit 10 has the apparatus 100 of the chip operate so that the latch circuits in the respective sequential circuits 20 are driven by the clock CLK output from the respective choppers 25.

At Step S15, a semiconductor test device executes a function test of the apparatus 100 as a whole (usual wafer test), and the amplitude adjustment circuit 10 lowers stepwise the VSSL voltage so that the amplitude of the clock CLK output from the chopper 25 increases until a testing result becomes normal at Step S16. The amplitude adjustment circuit 10 distributes the VSSL voltage having lowered stepwise to the choppers 25 by the voltage setting circuit 61 at Step S13. The choppers 25 output the clock CLK at the amplitude corresponding to the VSSL voltage having lowered stepwise.

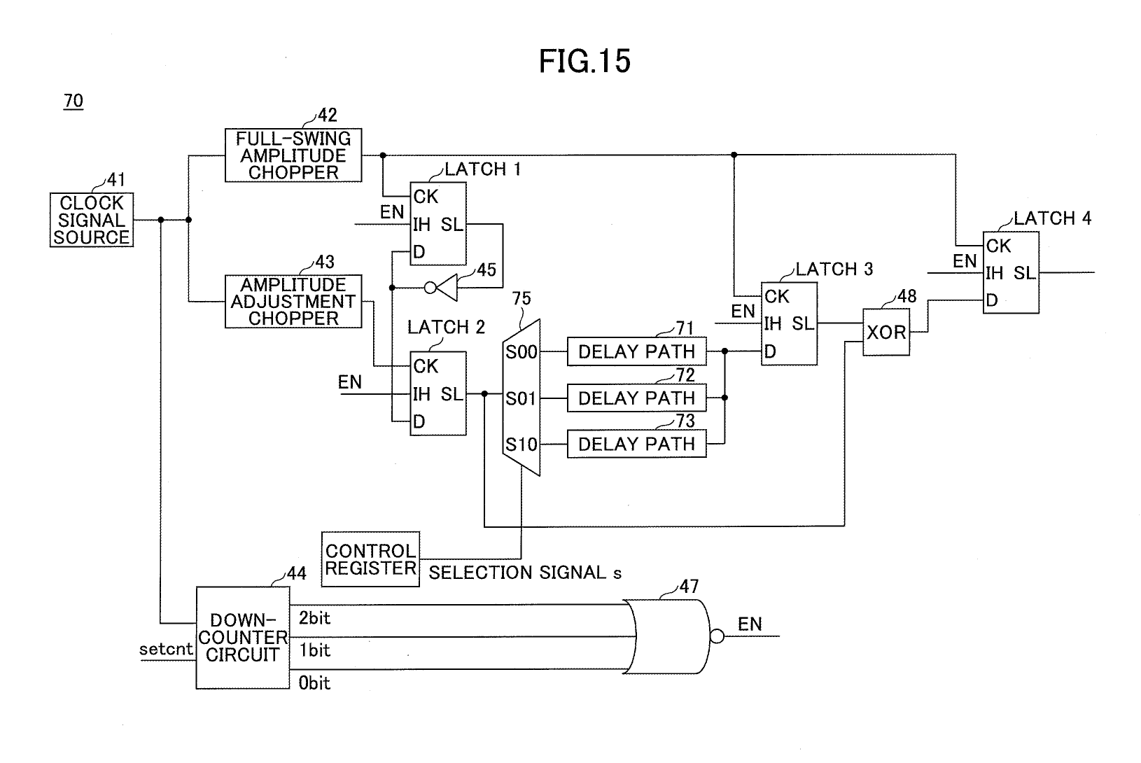

FIG. 15 is a configuration diagram illustrating an example of a malfunction detection circuit different from the above example. The malfunction detection circuit 70 in FIG. 15 and the malfunction detection circuit 40 in FIG. 8 differ in the critical path between the latch circuit 2 and the latch circuit 3.

The malfunction detection circuit 70 in FIG. 15 has multiple critical paths configured with multiple types of logic elements such as AND gates, OR gates, and the like (delay paths 71, 72, and 73). The delay paths 71, 72, and 73 have the propagation delay times different from each other. The demultiplexer 75 is a timing adjustment circuit to adjust the propagation delay time of the critical path by selecting the type of the critical path among the delay paths 71, 72, and 73 depending on a selection signal “s” determined by a control register. Multiple candidates of the critical path are provided for the amplitude adjustment of the clock CLK of the choppers 25, with which the VSSL voltage can be determined by a more correct model.

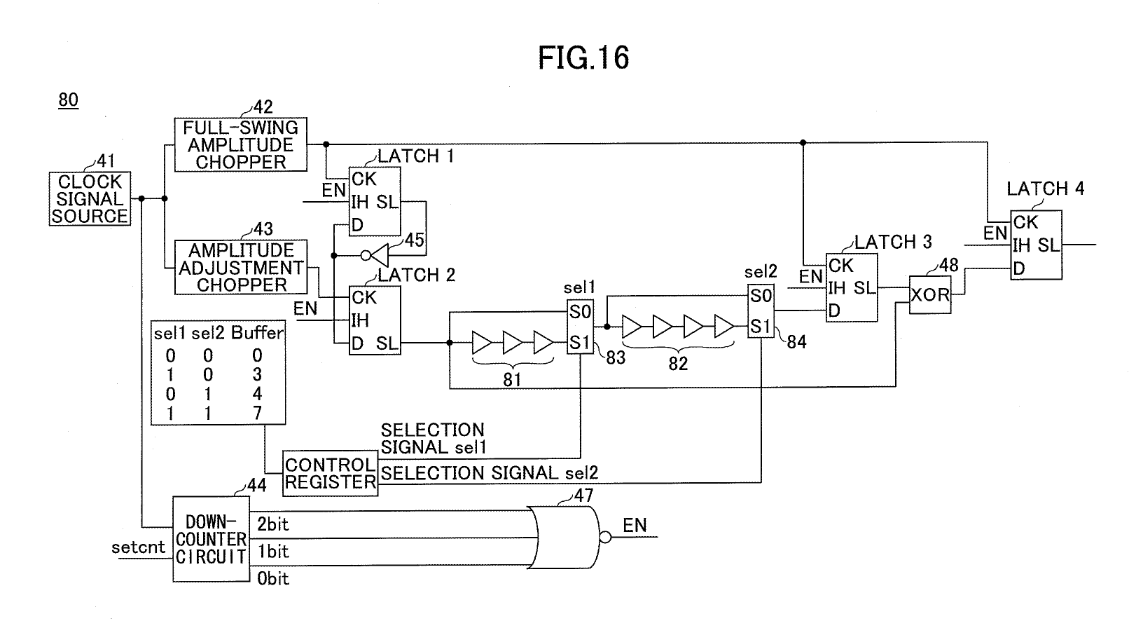

FIG. 16 is a configuration diagram illustrating an example of a malfunction detection circuit different from the above examples. The malfunction detection circuit 80 in FIG. 16 and the malfunction detection circuit 40 in FIG. 8 differ in the critical path between the latch circuit 2 and the latch circuit 3.

The malfunction detection circuit 80 in FIG. 16 includes a critical path whose propagation delay time can be changed after being implemented in the apparatus 100. Demultiplexers 83 and 84 constitute a timing adjustment circuit to adjust the propagation delay time of the critical path stepwise after being implemented in the apparatus 100 by changing the number of levels of buffers 81 and 82 on the critical path depending on selection signals sel1 and sel2 determined by a control register.

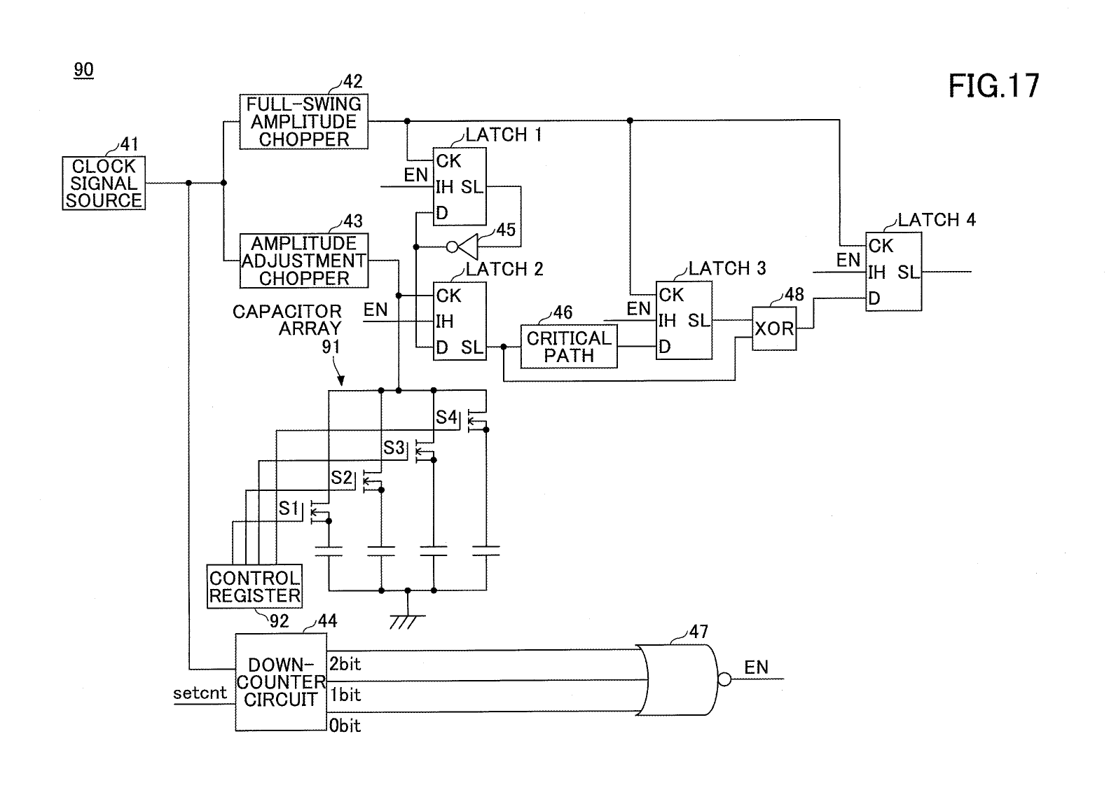

FIG. 17 is a configuration diagram illustrating an example of a malfunction detection circuit different from the above examples. The malfunction detection circuit 90 in FIG. 17 and the malfunction detection circuit 40 in FIG. 8 differ in the load that is connected with the output of the adjustment chopper 43.

The malfunction detection circuit 90 in FIG. 17 includes a capacitor array 91 as the load of the adjustment chopper 43 connected in parallel with the latch circuit 2. Switches S1, S2, S3, and S4 are provided for respective capacitors in the capacitor array 91. The amplitude adjustment circuit 10 can change the capacitance of the capacitor array 91 by turning on or off the switches S1, S2, S3, and S4 depending on a control register 92. By changing the capacitance of the capacitor array 91, a state can be created as if an arbitrary number of latch circuits were connected with the output of the adjustment chopper 43, and the VSSL voltage can be determined that reflects the state.

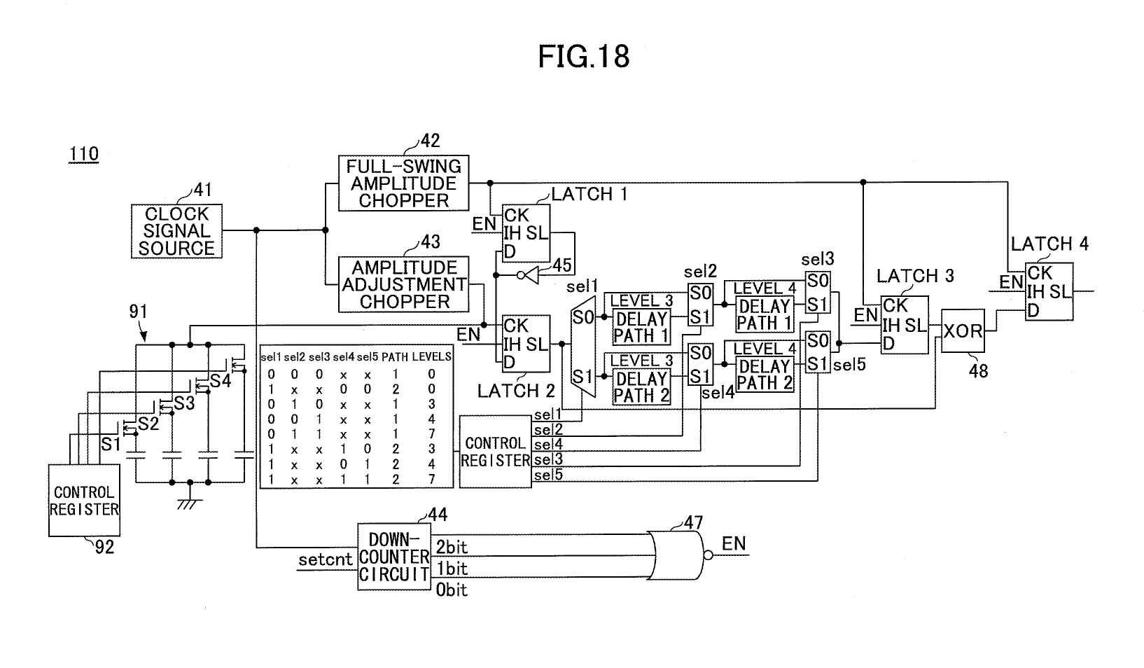

FIG. 18 is a configuration diagram illustrating an example of a malfunction detection circuit different from the above examples. It is possible to combine the selection function of the type of the data path, the selection function of the number of levels of the buffer, and the selection function of the load capacitance of the adjustment chopper, which are illustrated in FIGS. 15, 16, and 17, respectively. The malfunction detection circuit 110 in FIG. 18 is a circuit that includes all of these selection functions.

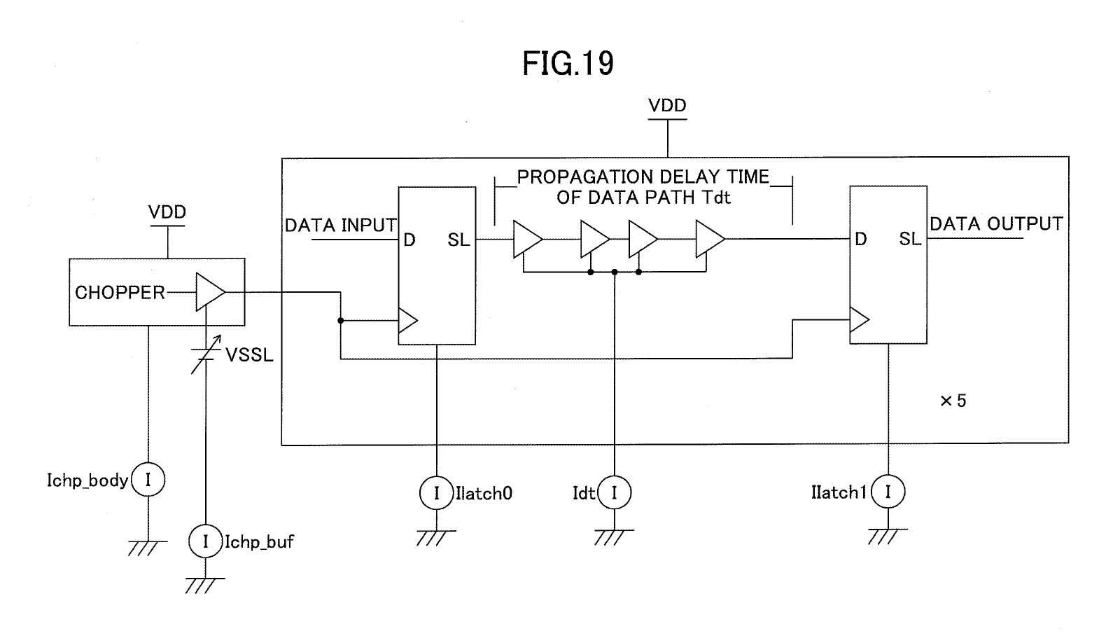

FIG. 19 is a configuration diagram illustrating an example of a circuit to simulate a power consumption reduction effect. The simulation circuit includes a data path configured with master-slave-type D-latches (flip-flops) and buffers, and a chopper that supplies a clock to the latch circuits. A mark “x5” means that there are five sequential circuits that are configured with the master-slave-type D-latches (flip-flops) and the buffers, respectively, and the chopper supplies the clock to these five sequential circuits.

To evaluate the power consumption of the simulation circuit as a whole, an ammeter Ichp_buf, an ammeter Ichp_body, an ammeter Ilatch0, an ammeter Ilatch1, and an ammeter Idt are provided. The ammeter Ichp_buf is provided between the power source VSSL and the ground to adjust the amplitude of the chopper. The power source VSSL is provided on the ground side of the output buffer of the chopper (driver). The ammeter Ichp_body is provided between the circuit other than the output buffer of the chopper and the ground. The ammeter Ilatch0 is provided between the master-slave-type D-latch transmitting data and the ground. The ammeter Ilatch1 is provided between the master-slave-type D-latch receiving the data and the ground. The ammeter Idt is provided between the buffers configuring the data path and the ground.

This simulated test simulates the power consumption of the simulation circuit as a whole and change of the propagation delay time Tdt of the data path at least one of amplitude adjustment and power adjustment is executed. The amplitude adjustment is to adjust the output amplitude of the chopper, and the power adjustment is to adjust the power supply voltage VDD.

The power consumption of the simulation circuit as a whole is calculated by converting currents obtained by the ammeters into electric charge by integrating over the simulation time, and by obtaining a product of the converted electric charge, the power supply voltage, and the clock frequency (the frequency of data for the data path).

Simulation conditions when executing the amplitude adjustment are set in that the power supply voltage VDD is set to a constant; and the junction temperature is set to 90° C. Also, the power supply voltage of the power source VSSL is changed so that the amplitude of the clock of the chopper is changed from the maximum voltage of the full-swing amplitude to 60% of the maximum voltage.

The simulation conditions when executing the power adjustment are set in that the power supply voltage VDD is changed in a range between the maximum value and 90% of the maximum value; and the junction temperature is set to 90° C. Also, the power supply voltage of the power source VSSL is set so that the amplitude of the clock of the chopper is the maximum voltage of the full-swing amplitude.

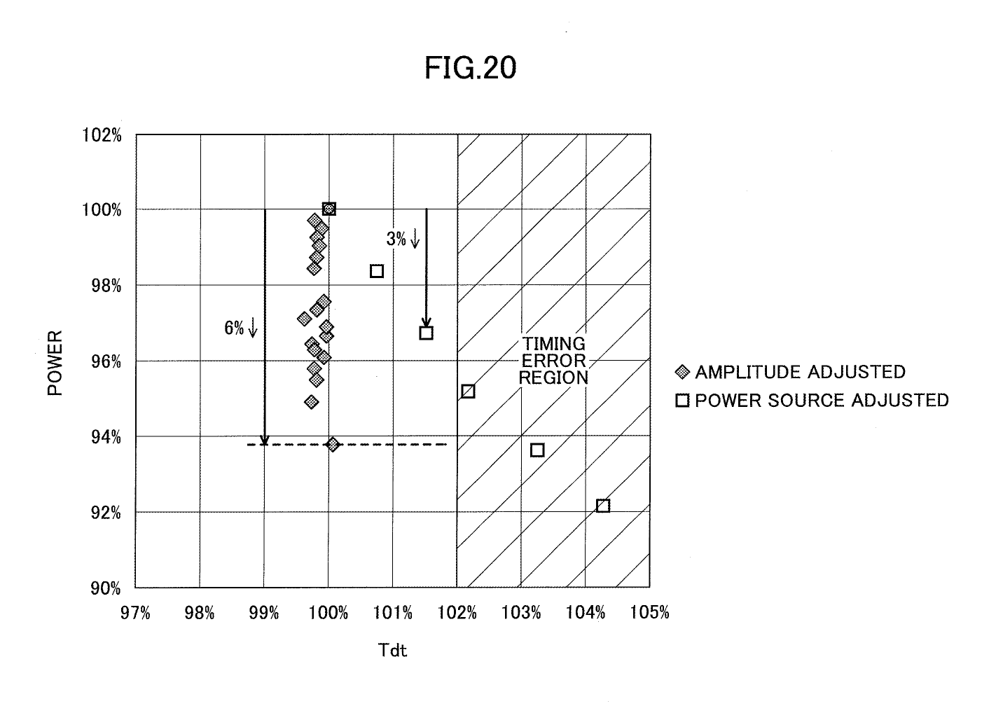

FIG. 20 is a diagram illustrating an example of a simulation result. In terms of a relationship between the propagation delay time Tdt of the data path and the power consumption, by the power adjustment, the propagation delay time Tdt increases while the power consumption reduces. Slant lines in FIG. 20 designates a region where the increase of the propagation delay time Tdt is greater than or equal to 2%, with which a timing error occurs, and the circuit does not operate. In the range where a timing error does not occur, the power consumption can be lowered by 3% by the power adjustment. On the other hand, by the amplitude adjustment, the propagation delay time Tdt is virtually constant even though the power consumption is lowered. The power consumption can be lowered by 6% at the maximum in the range where the latch circuits can be driven. By the amplitude adjustment, the power consumption can be lowered 3% more than by the power adjustment. Therefore, the amplitude adjustment results in a better power-to-performance ratio than the power adjustment.

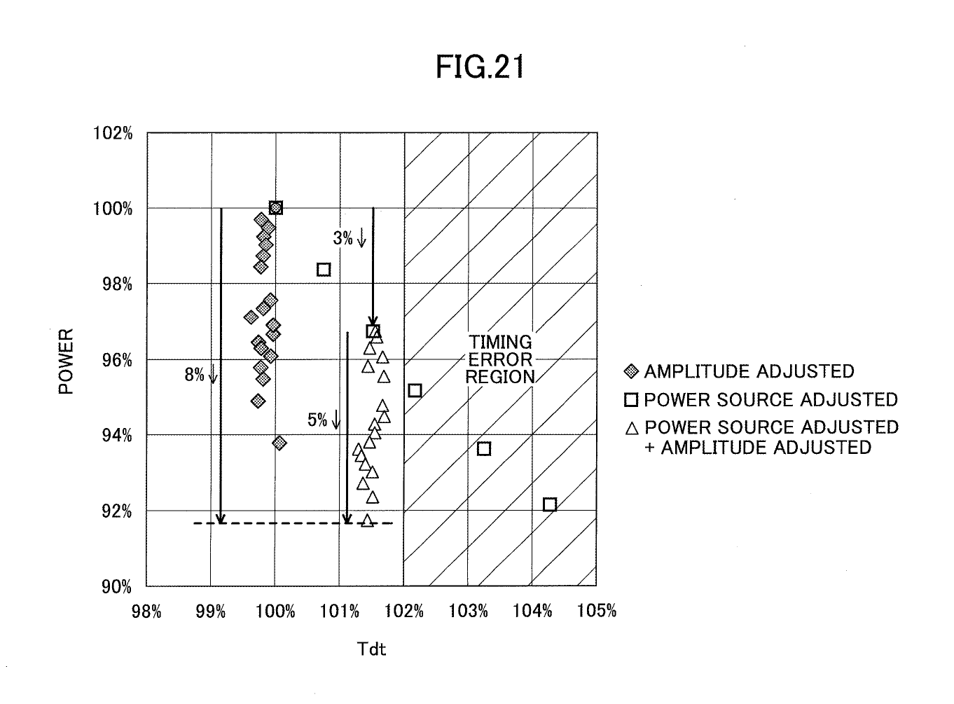

FIG. 21 is a diagram illustrating an example of a simulation result where the power adjustment and the amplitude adjustment are executed in combination. Namely, in a state where the power supply voltage is fixed to a voltage when the power consumption is lowered by 3%, the amplitude of the clock of the chopper is changed from the maximum voltage at the full-swing amplitude to 63% of the maximum voltage. The junction temperature is set to 90° C.

By combining the power adjustment and the amplitude adjustment, the power consumption can be reduced by 5% more, in addition to the reduction of the power consumption by 3% obtained by the power adjustment only. Compared to the power consumption obtained when the power supply voltage and the amplitude of the clock are at 100%, the power consumption can be reduced by 8%.

Namely, the amplitude adjustment can be combined with the power consumption reduction technology by the power adjustment, which is a general-purpose method having a considerably high power consumption reduction effect.

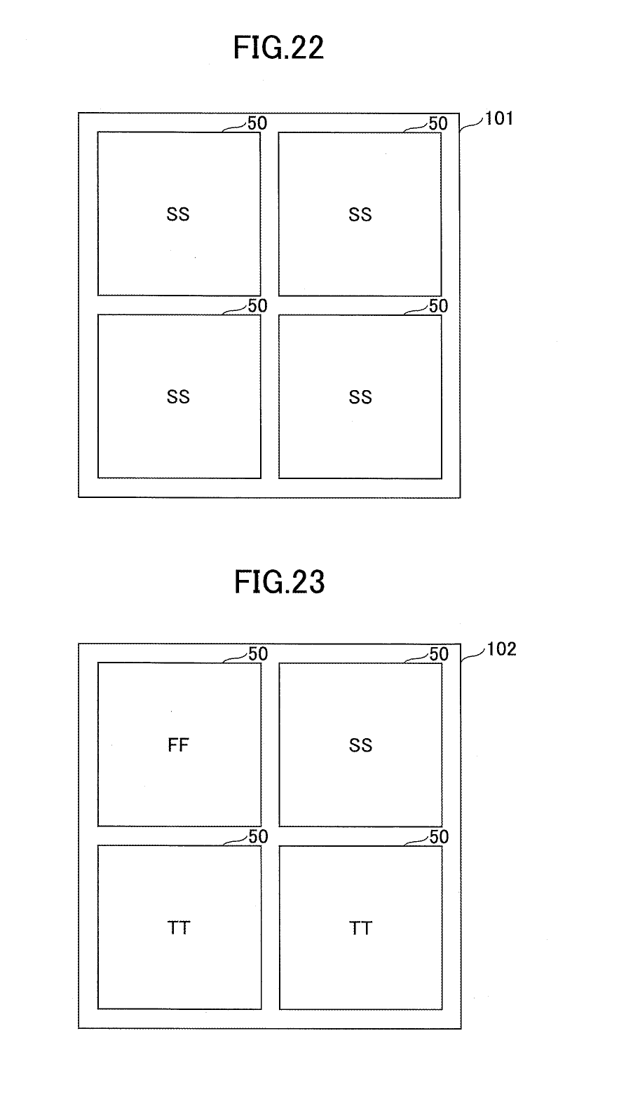

FIG. 22 illustrates an example of the semiconductor integrated circuit apparatus 101 having no manufacturing variation among the circuit blocks 50, and FIG. 23 illustrates an example of the semiconductor integrated circuit apparatus 102 having a manufacturing variation among the circuit blocks 50. Marks FF, TT, and SS represent manufacturing variations where the TT represent a typical variation, the FF represents a variation having distribution of the performance 1σ higher than the TT, and the SS represents a variation having distribution of the performance 1σ lower than the TT.

One simulation circuit of the FIG. 19 is disposed in each of the circuit blocks 50. A simulation is performed where the sum of the power of the respective circuit blocks 50 is defined as the power consumption of the semiconductor integrated circuit apparatus as a whole.

The power consumption of the simulation circuit as a whole is calculated by converting currents obtained by the ammeters into electric charge by integrating over the simulation time, and by obtaining a product of the converted electric charge, the power supply voltage, and the clock frequency (the frequency of data for the data path).

Simulation conditions for the case having no manufacturing variation are set in that the junction temperature is set to 90° C. Also, the power supply voltage of the power source VSSL is changed so that the amplitude of the clock of the chopper is changed from the maximum voltage of the full-swing amplitude to 60% of the maximum voltage. Simulation conditions when executing the power adjustment are set in that the power supply voltage VDD is changed in a range between the maximum value and 98% of the maximum value; and the junction temperature is set to 90° C. Also, the power supply voltage of the power source VSSL is set so that the amplitude of the clock of the chopper is the maximum voltage of the full-swing amplitude.

Simulation conditions for the case having a manufacturing variation are set in that the junction temperature is set to 90° C. Also, the power supply voltage of the power source VSSL is changed so that the power consumption of the individual circuit block 50 is minimum. Simulation conditions when executing the power adjustment are the same as those for the case having no manufacturing variation.

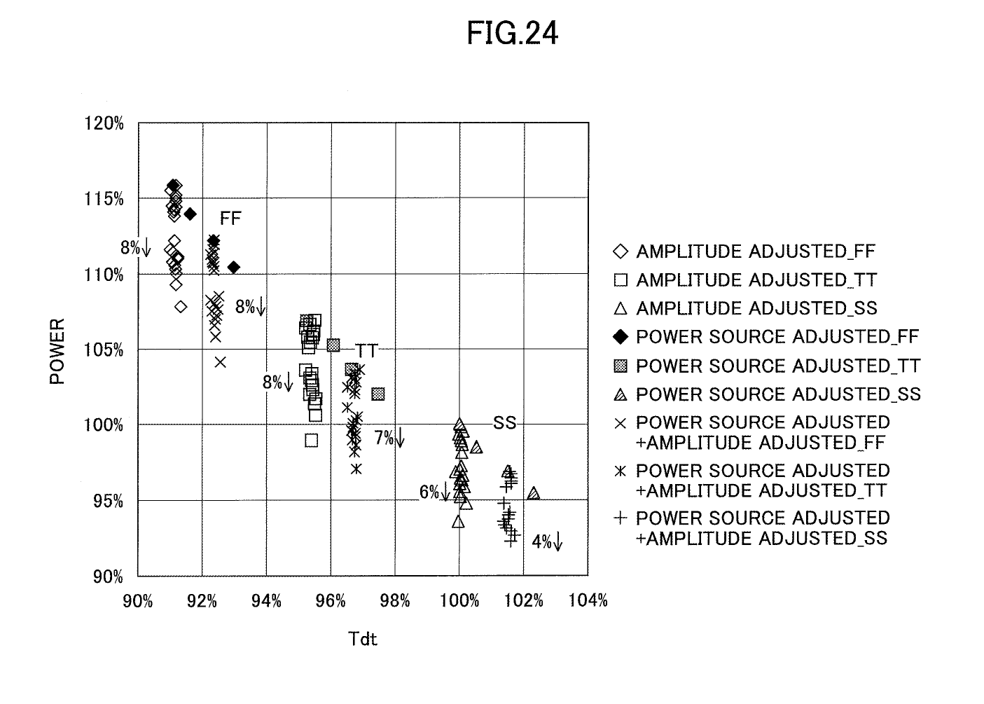

FIG. 24 is an example of a simulation result of the power consumption with respect to the propagation delay time Tdt of the circuit blocks 50 having the FF, TT, and SS conditions, respectively. The power supply voltage VDD of the SS condition is the maximum. The propagation delay time Tdt of the data path and the power consumption are at 100% when the amplitude of the clock is the maximum voltage of the full-swing amplitude.

By the power adjustment, the propagation delay time Tdt increases while the power consumption reduces. On the other hand, by the amplitude adjustment, the propagation delay time Tdt is virtually constant even though the power consumption is lowered.

When the power supply voltage VDD is maximum, the power consumption can be lowered by 6% to 8% by the amplitude adjustment. If the propagation delay time Tdt of the SS condition is allowed to increase up to 2%, after the power supply voltage VDD has been lowered, the amplitude adjustment can be further applied. In this case, the power consumption can be lowered by 8% to 12%.

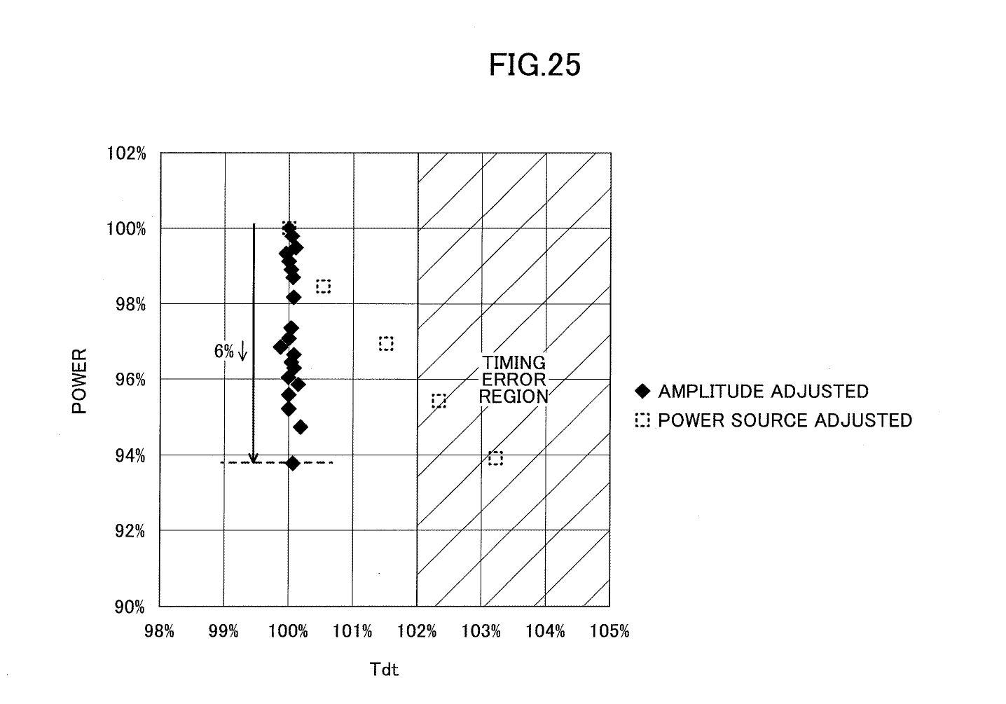

FIG. 25 is an example of a simulation result where a relationship between the propagation delay time Tdt and the power consumption of the semiconductor integrated circuit as a whole is inspected for a case having no manufacturing variation among the circuit blocks 50 as in FIG. 22.

By the power adjustment, the propagation delay time Tdt increases while the power consumption reduces. Slant lines in FIG. 25 designates a region where the increase of the propagation delay time Tdt is greater than or equal to 2%, with which a timing error occurs, and the circuit does not operate. In the range where a timing error does not occur, the power consumption can be lowered by 3% by the power adjustment. On the other hand, by the amplitude adjustment, the propagation delay time Tdt is virtually constant even though the power consumption is lowered. The power consumption can be lowered by 6% at the maximum in the range where the latch circuits can be driven. By the amplitude adjustment, the power consumption can be lowered 2% more than by the power adjustment.

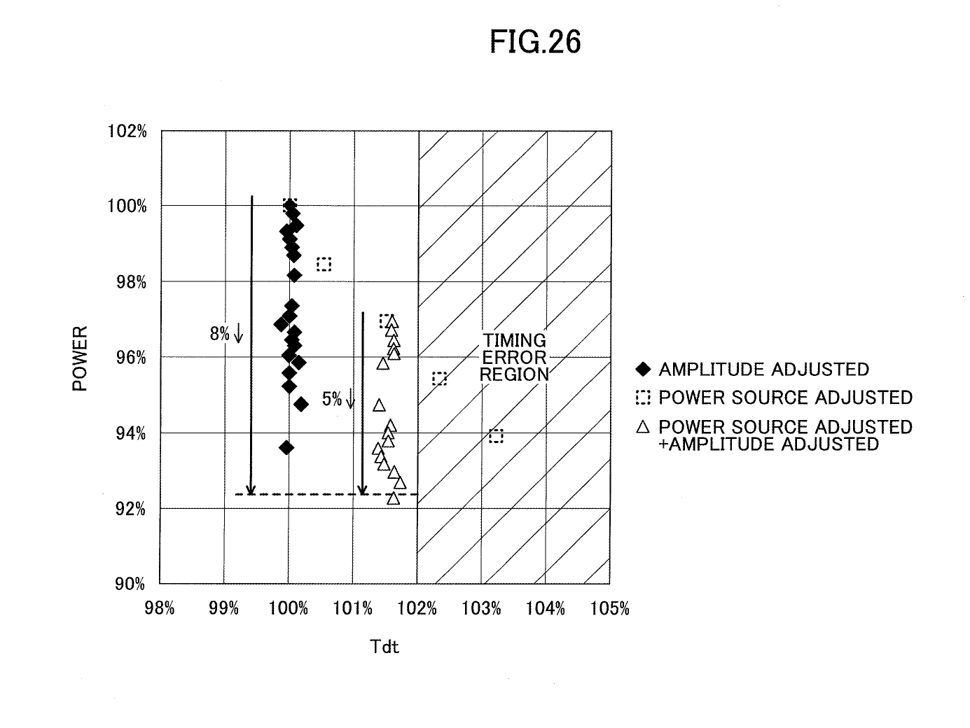

FIG. 26 is a diagram illustrating an example of a simulation result where the power adjustment and the amplitude adjustment are executed in combination for a case having no manufacturing variation among the circuit blocks 50 as in FIG. 22. Slant lines in FIG. 26 designates a region where the increase of the propagation delay time Tdt is greater than or equal to 2%, with which a timing error occurs, and the circuit does not operate.

By combining the power adjustment and the amplitude adjustment, the power consumption can be reduced by 5% more, in addition to the reduction of the power consumption by 3% obtained by the power adjustment only. Compared to the power consumption obtained when the power supply voltage and the amplitude of the clock are at 100%, the power consumption can be reduced by 8%.

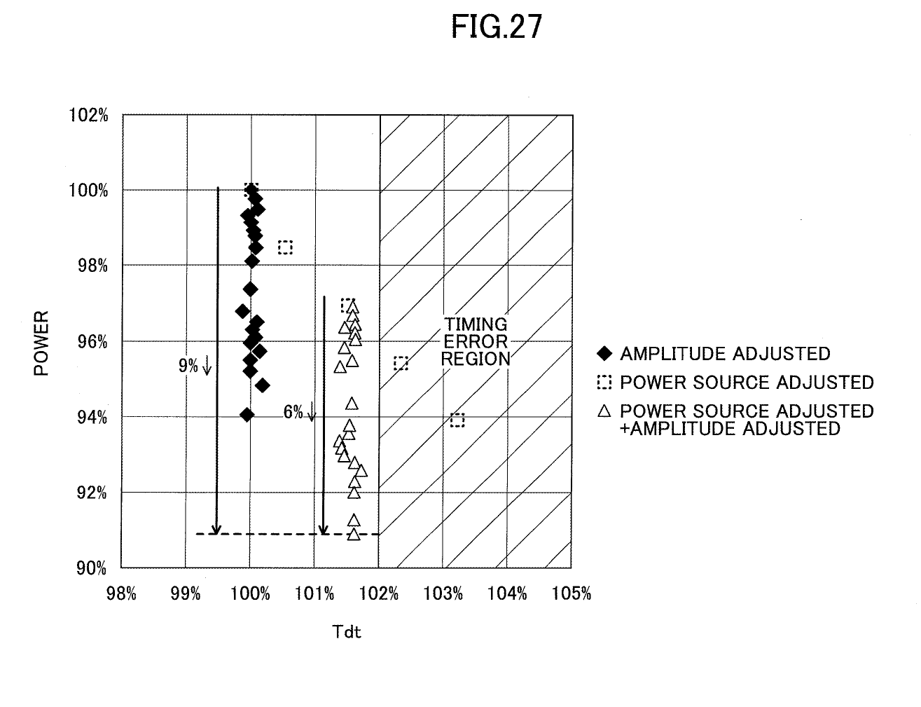

FIG. 27 is an example of a simulation result where a relationship between the propagation delay time Tdt and the power consumption of the semiconductor integrated circuit as a whole is inspected for a case having a manufacturing variation among the circuit blocks 50 as in FIG. 23.

From the view point of the semiconductor integrated circuit apparatus as a whole, the performance of the semiconductor integrated circuit apparatus is determined by the performance of the circuit block of the SS condition. The value of the propagation delay time Tdt is set to the value of the SS condition, and the power consumption is the sum the electric power of the circuit blocks 50.

By the power adjustment, the power consumption can be lowered by 3%. On the other hand, by the amplitude adjustment, the power consumption can be lowered by 6% when the power supply voltage VDD is maximum.

Also, by combining the power adjustment and the amplitude adjustment, the power consumption can be reduced by 6% more, in addition to the reduction of the power consumption by 3% obtained by the power adjustment only. Compared to the power consumption obtained when the power supply voltage is at the maximum, the power consumption can be reduced by 9%.

In this way, by placing multiple circuits for adjusting the amplitude of the clock of the chopper, the amplitude adjustment can be executed to cope with a manufacturing variation.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that various changes, substitutions, and alterations could be made hereto without departing from the spirit and scope of the invention.

What is claimed is:

1. A semiconductor integrated circuit apparatus comprising:
a plurality of circuit blocks configured to include a plurality of latch circuits connected via a data path, and a chopper to output a clock to have operations of the latch circuits synchronized; and
an amplitude adjustment circuit configured to be capable of adjusting an amplitude of the clock of each of the circuit blocks to a voltage different from each other.

2. The semiconductor integrated circuit apparatus as claimed in claim 1, wherein the amplitude adjustment circuit lowers the amplitude within a range where the operations of the latch circuits can be synchronized.

3. The semiconductor integrated circuit apparatus as claimed in claim 2, wherein the amplitude adjustment circuit adjusts the amplitude so that a propagation delay time of the latch circuit does not exceed a target delay time.

4. The semiconductor integrated circuit apparatus as claimed in claim 1, wherein the amplitude adjustment circuit sets the amplitude of each of the circuit blocks to a voltage derived by using the critical path of each of the circuit blocks.

5. The semiconductor integrated circuit apparatus as claimed in claim 4, each of the circuit blocks further includes a time adjustment circuit configured to adjust the propagation delay time of the critical path.

6. The semiconductor integrated circuit apparatus as claimed in claim 5, wherein each of the circuit blocks includes a plurality of delay paths having propagation delay times different from each other,
wherein the time adjustment circuit selects the critical path among the delay paths.

7. The semiconductor integrated circuit apparatus as claimed in claim 5, wherein the time adjustment circuit changes a number of the buffers on the critical path.

8. a power consumption reduction method of a semiconductor integrated circuit apparatus including a plurality of circuit blocks configured to include a plurality of latch circuits connected via a data path, and a chopper to output a clock to have operations of the latch circuits synchronized, the method comprising:
adjusting an amplitude of the clock of each of the circuit blocks to a voltage different from each other.
